(19) United States
(12) Patent Application Publication
(10) Pub. No.: US 2022/0223472 A1
(43) Pub. Date: Jul. 14, 2022

(54) Ruthenium Reflow For Via Fill

(71) Applicant: Applied Materials, Inc., Santa Clara, CA (US)

(72) Inventors: Yi Luo, Santa Clara, CA (US); Rong Tao, San Jose, CA (US); Liqi Wu, San Jose, CA (US); Mingte Liu, San Jose, CA (US); Joung Joo Lee, San Jose, CA (US); Avgerinos V. Gelatos, Scotts Valley, CA (US)

(73) Assignee: Applied Materials, Inc., Santa Clara, CA (US)

(21) Appl. No.: 17/145,520

(22) Filed: Jan. 11, 2021

(51) Int. Cl. H01L 21/768

(52) U.S. Cl. CPC H01L 21/76882; H01L 23/53252; H01L 21/76843

(57) ABSTRACT

A method for forming conductive structures for a semiconductor device includes depositing a reflow material in features, e.g. vias, formed in a dielectric layer. A high melting point material is deposited in the feature and is reflowed and annealed in an ambient comprising one or more of hydrogen molecules, hydrogen ions, and hydrogen radicals at a temperature greater than 300° C. to fill the feature with a reflow material.

### TECHNICAL FIELD

Embodiments of the disclosure relates to semiconductor devices and methods of manufacture. More particularly, embodiments of the disclosure are directed to reflow of ruthenium to fill via structures.

### BACKGROUND

Generally, an integrated circuit (IC) refers to a set of electronic devices, e.g., transistors formed on a small chip of semiconductor material, typically, silicon. Typically, the IC includes one or more layers of metallization having metal lines to connect the electronic devices of the IC to one another and to external connections. Typically, layers of the interlayer dielectric material arc placed between the metallization layers of the IC for insulation.

Semiconductor processing is often guided by ever decreasing node sizes. As dimensions shrink, further challenges arise in many processing steps and structures. This includes interconnect structures, which as a result of reduced node size suffers from resistivity issues and formation issues. At small dimensions (e.g., critical dimensions (CD) under 30 nm), interconnect fills with any kind of metal are very challenging. This is further complicated for high melting point metals, which are difficult to process, and their high temperature processing can result in damaging effects to surrounding materials and structures.

Ruthenium (Ru) is a candidate for 2 nm and beyond technologies, owing to its low resistivity and less resistivity size effect. Due to further volume shrinkage of middle end of line structures, however, Ru and other conformal metal fills are extremely difficult as structure profile plays a critical role. Atomic layer deposition (ALD) and chemical vapor deposition (CVD) conformal fill processes lead to voids inside the structure due to inconsistent overhang or structure bowing. Unlike Cu and Co, which have meting points of 1085° C. and 1495° C., respectively, ruthenium (Ru) has a higher melting temperature of 2334° C., and, hence, ruthenium is difficult to enable surface diffusion for reflow. Accordingly, there is a need for improved methods of filling interconnect structures, e.g. vias, with high melting point materials.

### SUMMARY

One or more embodiments of the disclosure are directed to methods of depositing films. In one or more embodiments, a method of depositing a film comprises: depositing a ruthenium reflow material on a substrate, the substrate comprising at least one via; reflowing the ruthenium reflow material to fill the at least one via; and exposing the substrate to an annealing environment comprising one or more of hydrogen molecules, hydrogen ions, and hydrogen radicals at a temperature greater than 300° C. to anneal the ruthenium reflow material.

Further embodiments of the disclosure are directed to methods for forming conductive structures for a semiconductor device. In one or more embodiments, a method for forming conductive structures for a semiconductor device comprises: patterning a dielectric layer to form at least one via in the dielectric layer; depositing a liner layer on the dielectric layer an in the at least one via; conformally depositing a ruthenium reflow material on the liner layer; reflowing the ruthenium reflow material to fill the at least one via; and exposing the ruthenium reflow material to an annealing environment comprising one or more of hydrogen molecules, hydrogen ions, and hydrogen radicals at a temperature greater than 300° C. to anneal the ruthenium reflow material.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of the disclosure and are therefore not to be considered limiting of its scope, for the disclosure may admit to other equally effective embodiments.

FIG. 1 illustrates a process flow diagram of a method in accordance with one or more embodiments of the disclosure;

FIG. 2 illustrates a cross-section view of a substrate in accordance with one or more embodiments of the disclosure;

FIG. 3 illustrates a cross-section view of a substrate in accordance with one or more embodiments of the disclosure;

FIG. 4 illustrates a cross-section view of a substrate in accordance with one or more embodiments of the disclosure; and

FIG. 5 illustrates a cross-section view of a substrate in accordance with one or more embodiments of the disclosure.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

Many of the details, dimensions, angles and other features shown in the Figures are merely illustrative of particular embodiments. Accordingly, other embodiments can have other details, components, dimensions, angles and features without departing from the spirit or scope of the present disclosure. In addition, further embodiments of the disclosure can be practiced without several of the details described below.

A “substrate,” “substrate surface,” or the like, as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present invention, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

One or more embodiments provide methods of filling features on a substrate. As used herein, the term “feature” refers to a metal line, a via, a single damascene structure, a dual damascene structure, and the like. In specific embodiments, the methods employed herein are used for filling at least one via on a substrate. In one or more embodiments, a high melting point metal, e.g. ruthenium (Ru), is deposited and then annealed to allow the reflow of the high melting point metal to fill the feature, e.g. via, without a void.

Via structures are becoming more challenging for fill due to decreasing critical dimension. The via structure may also have bowing/overhang at the bottom, making ALD/CVD conformal processes difficult to fill without creating a void. This would cause Rc increase and degrade device performance. Accordingly, in one or more embodiments, a feature may be first deposited with a layer of ruthenium (Ru) without closing the feature, then enable reflow with hydrogen molecules/hydrogen ions/hydrogen radicals (H+/H*) thermal annealing. In one or more embodiments, the ruthenium film surface diffusion is activated to have net flux moving inside the structure to decrease surface area and minimize total surface energy. Meanwhile, the hydrogen molecules/hydrogen ions/hydrogen radicals (H+/H*) species help remove the impurities and the high temperature promotes grain regrowth, resulting in resistivity reduction.

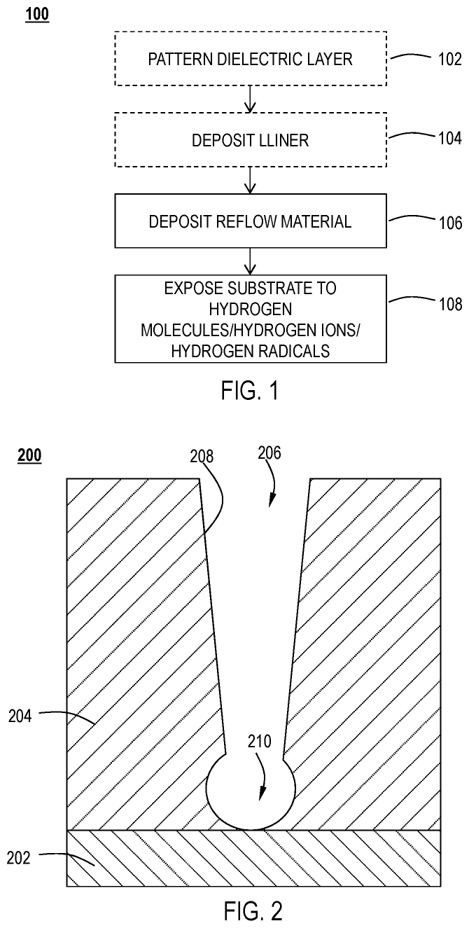

With reference to FIG. 1, one or more embodiments of the disclosure are directed to a method 100 of depositing a film. The method illustrated in FIG. 1 is representative of a deposition process to fill a feature, particularly a via, with a high melting point metal, specifically ruthenium (Ru). FIGS. 2 through 5 illustrate cross-sectional view of a semiconductor device 200 according to one or more embodiments. The semiconductor device 200 can include any device having a conductive line, via, trench, interconnect or other conductive structure or structures. Such devices can include complementary metal oxide semiconductor (CMOS) devices) or any other type of semiconductor device. The device 200 comprises a substrate 202 having one or more layers formed thereon.

The substrate 202 can include any suitable substrate structure, e.g., a bulk semiconductor a semiconductor-on-insulator (SOI) substrate, etc. In one or more embodiments, the substrate 202 can include a silicon-containing material. Illustrative examples of Si-containing materials suitable for the substrate 202 can include, but are not limited to, silicon (Si), silicon germanium (SiGe), silicon germanium carbide (SiGeC), silicon carbide (SiC) and multi-layers thereof. Although silicon is the predominantly used semiconductor material in wafer fabrication, alternative semiconductor materials can be employed, such as, but not limited to, germanium, gallium arsenide, gallium nitride, silicon germanium, cadmium telluride, zinc selenide, and the like. In some embodiments, the substrate 202 comprises a metallic material. In one or more embodiments, the metallic material comprises one or more of tungsten (W), ruthenium (Ru), copper (Cu), titanium (Ti), gold (Au), silver (Ag), platinum (Pt), and the like, and alloys thereof.

Referring to FIGS. 1 through 5, at operation 102, in one or more embodiments, a dielectric material 204 on the substrate 202 is optionally patterned and etched to form at least one dimensioned feature 206, e.g. vias, trenches, and the like. In one or more embodiments, the at least one feature 206 has at least one sidewall 208 and a feature bottom 208. These features can have small dimensions (e.g., less than about 20 nm). In one or more embodiments, the at least one feature 206, e.g. the at least one via, has a critical dimension less than 30 nm, including less than 20 nm, and less than 15 nm. In some embodiments, the at least one feature 206, e.g. the at least one via, has a critical dimension is in a range of from 9 nm to 13 nm. In one or more embodiments, the at least one feature 206, e.g. the at least one via, has an aspect ratio in a range of from 4:1 to 10:1.

In other embodiments, a substrate 202 having at least one feature thereon is provided. In some embodiments, the substrate 202 comprises a dielectric material 204. As used herein, the term “dielectric material” refers to a layer of material that is an electrical insulator that can be polarized in an electric field. The dielectric material 204 can comprise any suitable material known to the skilled artisan. In one or more embodiments, the dielectric material comprises one or more of oxides, carbon doped oxides, silicon oxide (SiO), porous silicon dioxide (SiO₂), silicon oxide (SiO), silicon nitride (SiN), silicon oxide/silicon nitride, carbides, oxycarbides, nitrides, oxynitrides, oxycarbonitrides, polymers, phosphosilicate glass, fluorosilicate (SiOF) glass, or organosilicate glass (SiOCH). In specific embodiment, the dielectric material comprises one or more of silicon nitride (SiN) and silicon oxide (SiO₂).

The dielectric layer 204 may be patterned using any suitable technique known to the skilled artisan. In one or more embodiments, the dielectric layer 204 is patterned using one or more of lithographic processing, reverse image transfer, sidewall image transfer, or the like. The at least one feature 206 can be etched using a reactive ion etch (RIE) process or other anisotropic etch process. Different etch masks may be employed and can employ blocking masks to form the at least one feature 206 of different depths or sizes.

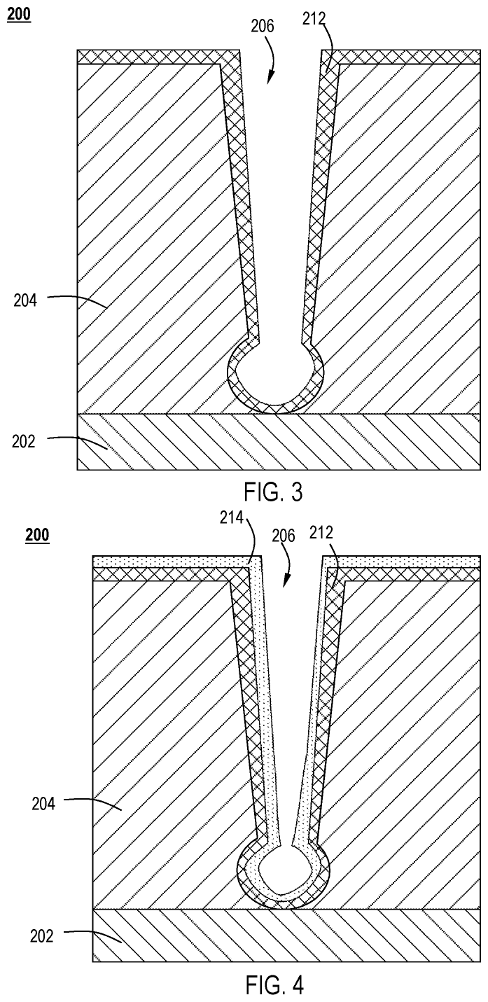

With reference to FIG. 1 and FIG. 3, at operation 104, an optional liner layer 212 may be deposited in the at least one feature 206. In one or more embodiments, the optional liner layer 212 is deposited to line the topography of the dielectric layer 204 and the line the exposed portion of the substrate 202 in the at least one feature 206. The optional liner layer 212 can be any suitable material that can increase adhesion of the ruthenium to the substrate. In one or more embodiments, the liner layer 212 comprises on or more of tantalum (Ta), titanium (Ti), tantalum nitride (TaN), titanium nitride (TiN), ruthenium/tantalum nitride (Ru/TaN), tungsten (W), molybdenum (Mo), and ruthenium (Ru). The optional liner layer 212 can be deposited by any suitable technique known to the skilled artisan including, but not limited to, atomic layer deposition (ALD), chemical vapor deposition (CVD), physical vapor deposition (PVD), evaporation or plating.

In one or more embodiments, the liner layer 212 is a non-conformal liner. In other embodiments, the liner layer 212 is a conformal liner layer and the liner layer 212 is substantially conformal to the underlying dielectric material 204. As used herein, a layer or a liner which is “substantially conformal” refers to a layer where the thickness is about the same throughout (e.g., on the dielectric material 204, on the sidewalls 208 of the feature 206, and on the feature bottom 210). A layer which is substantially conformal varies in thickness by less than or equal to about 5%, 2%, 1% or 0.5.

In one or more embodiments, the liner layer 212 has a thickness in a range of from 0 Å to 30 Å, or in a range of from 1 Å to 30 Å, or in a range of from 2 Å to 20 Å, or in a range of from 3 Å to 10 Å.

Referring to FIG. 1 and FIG. 4, at operation 106, in one or more embodiments, a high melting point metal 214, e.g. a reflow material is deposited over the liner layer 212. In one or more embodiments, the high melting point metal 214 comprises one or more of ruthenium (Ru), titanium (Ti), vanadium (V), chromium (Cr), zirconium (Zr), hafnium (Hf), rhodium (Rh), osmium (Os), and iridium (Ir). In specific embodiments, the high melting point metal 214 comprises ruthenium (Ru). In one or more embodiments, the high melting point metal 214 is not deposited to fill the features, but instead merely lines the feature 206 (or the liner layer 212, if present) with a thin layer. In one or more embodiments, the deposition of the high melting point metal 214 is a conformal deposition. The high melting point metal 214 can be deposited by any suitable technique known to the skilled artisan including, but not limited to, atomic layer deposition (ALD), chemical vapor deposition (CVD), physical vapor deposition (PVD), evaporation or plating.

In one or more embodiments, the high melting point metal 214 can be deposited in a thin layer. In one or more embodiments, the deposited high melting point metal 214 has a thickness in a range of from 10 Å to 150 Å.

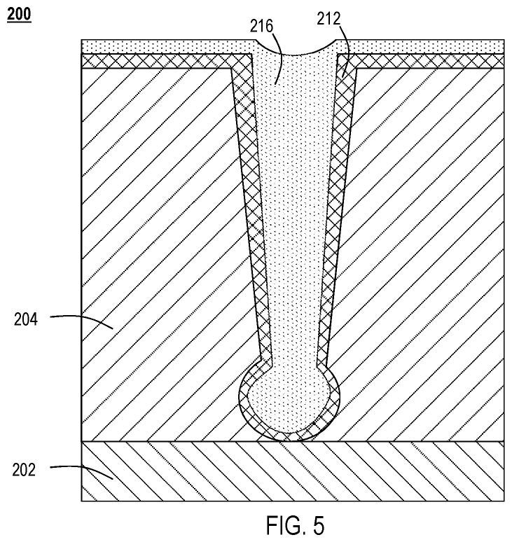

Referring to FIG. 1 and FIG. 5, at operation 108, a reflow process is performed to flow the high melting point material 214 and form a reflow material 216 to fill the at least one feature 206. In one or more embodiments, the high melting point material 214 flows without melting due to surface tension and the surface properties of the high melting point material 214. The reflow process includes annealing heat treatment below the melting point of the high melting point material 214.

In one or more embodiments, the device 200 with the high melting point metal 214 is exposed to an ambient comprising one or more of hydrogen molecules, hydrogen ions, and hydrogen radicals and is annealed to reflow the high melting point metal 214. The high melting point metal 214 settles within the at least one feature 206, e.g. the via, optionally on the liner layer 212. The high melting point 214 metal collects within the at least one feature 206, e.g. the via, and flows and fills the at least one feature 206 to form reflow material 216. As used herein, the term “reflow” refers to a thermal dynamically favored process to minimize total surface energy with net flux flowing inside the at least one feature 206 enabled by surface hopping. To enable reflow, it is critical to overcome the surface activation energy to activate surface hopping to ruthenium atoms.

In one or more embodiments, reflowing the high melting point 214 metal comprises reflowing at a temperature greater than 300° C. in an atmosphere comprising one or more of hydrogen molecules, hydrogen ions, and hydrogen radicals. In other embodiments, reflowing the high melting point 214 metal comprises reflowing at a temperature in a range of from 300° C. to 1000° C. in an atmosphere comprising one or more of hydrogen molecules, hydrogen ions, and hydrogen radicals. In some embodiments, the annealing temperature is greater than 400° C. or greater than 450° C.

Without intending to be bound by theory, it is thought that hydrogen molecules, hydrogen ions, and hydrogen radicals bond to the high melting point metal 214, e.g. ruthenium, and decrease the surface activation energy. Accordingly, the reflow and anneal does not have to be repeated in multiple cycles, but is complete after one cycle. In one or more embodiments, the deposition and reflow processes are not repeated.

In one or more embodiments, after exposing the substrate to the annealing ambient comprising hydrogen molecules, hydrogen ions, and hydrogen radicals at a temperature in a range of from 300° C. to 1000° C., the at least one feature is substantially filled with the reflow material 216. As used herein, the term “substantially filled” means that there is less than about 5%, including less than about 4%, less than about 3%, less than about 2%, less than about 1%, and less than about 0.5% of empty space remaining in the at least one feature. In one or more embodiments, the at least one feature 206 is substantially filled and no void is formed in the reflow material 216.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

1. A method of depositing a film, the method comprising:
depositing a ruthenium reflow material in at least one via on a substrate, the ruthenium reflow material only lining, not filling, the at least one via; and
reflowing the ruthenium reflow material by exposing the substrate to an annealing environment comprising one or more of hydrogen molecules, hydrogen ions, and hydrogen radicals at a temperature in a range of from greater than 300° C. to 1000° C. to fill the at least one via with the ruthenium reflow material.

2. The method of claim 1, wherein the substrate comprises a dielectric material.

3. The method of claim 1, wherein the substrate comprises a conformal liner.

4. The method of claim 3, wherein the conformal liner comprises one or more of titanium nitride (TiN), tantalum nitride (TaN), tungsten (W), molybdenum (Mo), and ruthenium (Ru).

5. The method of claim 4, wherein the conformal liner has a thickness in a range of from 0 Å to 30 Å.

6. The method of claim 1, wherein the at least one via has a critical dimension less than 30 nm.

7. The method of claim 6, wherein the critical dimension is in a range of from 9 nm to 13 nm.

8. The method of claim 1, wherein the at least one via has an aspect ratio in a range of from 4:1 to 10:1.

9. (canceled)

10. The method of claim 1, wherein, after exposing the substrate to the annealing environment, the at least one via is filled with the ruthenium reflow material with no void.

11. A method for forming conductive structures for a semiconductor device, the method comprising:
patterning a dielectric material to form at least one via in the dielectric material;
depositing a liner layer on the dielectric material and in the at least one via;
conformally depositing a ruthenium reflow material on the liner layer and in the at least one via, the ruthenium reflow material only lining, not filling, the at least one via; and
reflowing the ruthenium reflow material by
exposing the ruthenium reflow material to an annealing environment comprising one or more of hydrogen molecules, hydrogen ions, and hydrogen radicals at a temperature in a range of from greater than 300° C. to 1000° C. fill the at least one via with the ruthenium reflow material.

12. The method of claim 11, wherein the dielectric material comprises one or more of silicon nitride (SiN), silicon oxide (SiO₂).

13. The method of claim 11, wherein the liner layer comprises a conformal liner.

14. The method of claim 13, wherein the liner layer comprises one or more of titanium nitride (TiN), tantalum nitride (TaN), tungsten (W), molybdenum (Mo), and ruthenium (Ru).

15. The method of claim 14, wherein the liner layer has a thickness in a range of from 0 Å to 30 Å.

16. The method of claim 11, wherein the at least one via has a critical dimension less than 30 nm.

17. The method of claim 16, wherein the critical dimension is in a range of from 9 nm to 13 nm.

18. The method of claim 11, wherein the at least one via has an aspect ratio in a range of from 4:1 to 10:1.

19. (canceled)

20. The method of claim 11, wherein, after exposing the semiconductor device to the annealing environment, the at least one via is filled with the ruthenium reflow material with no void.

21. The method of claim 1, wherein the deposited ruthenium reflow material only lining, not filling, the at least one via, has a thickness in a range of from 10 Å to 150 Å.

22. The method of claim 11, wherein the conformally deposited ruthenium reflow material on the liner layer and in the at least one via only lining, not filling, the at least one via, has a thickness in a range of from 10 Å to 150 Å.
